(19) United States
(12) Patent Application Publication
(10) Pub. No.: US 2003/0178145 A1
(43) Pub. Date: Sep. 25, 2003

(54) Closed hole edge lift pin and susceptor for wafer process chambers

(75) Inventors: Roger N. Anderson, Sunnyvale, CA (US); Robert T. Trujillo, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/106,666

(22) Filed: Mar. 25, 2002

(51) Int. Cl. C23F 1/00; C23C 16/00

(52) U.S. Cl. 156/345.51; 118/728

(57) ABSTRACT

An apparatus that includes a susceptor having a number of through holes, a number of lift pins positioned within the through holes, each lift pin having a lift pin head able to translate a wafer by contacting the wafer at an outer diameter edge, the lift pins capable of extending to lift the wafer off the susceptor; and the lift pins capable of retracting to place the wafer onto the susceptor, and upon placing the wafer onto the susceptor, each of the lift pin heads are capable of contacting a floor of the susceptor for restricting flow of a gas through the through holes.

### FIELD OF THE INVENTION

The present invention relates to the field of processing a wafer and more particularly to the area of translating the wafer at the wafer edge with lift pins.

### DISCUSSION OF RELATED ART

In semiconductor wafer substrate (wafer) processing, the wafers can be placed into a single wafer process chamber (process chamber) and positioned onto a circular plate known as a susceptor for deposition of a film. After transferring the wafer into the process chamber, the wafer can be placed onto a ledge in the susceptor that surrounds a dished-out center area such that contact by the wafer with the susceptor is limited to the wafer edges in contact with the ledge. After processing, the wafer can be lifted from the susceptor and removed from the process chamber.

Several techniques have been developed for handling wafers during wafer exchange in a process chamber. FIG. 1A is an illustration of a process chamber with lift pins extended to raise a wafer above a susceptor. The lift pins (pins) are positioned through holes in the susceptor and through holes in a susceptor support and are attached to a pin lift structure. Upward movement of the pin lift can contact and extend the lift pins to raise the wafer off the susceptor surface, lowering the pin lift can lower the pins, which can lower the wafer onto the susceptor. A robot arm (blade) can release or accept the wafer from the extended pins for transfer in and out of the process chamber. This technique has a problem with scratches on the backside or non-device side (bottom) surface as a result of translating the wafer up and down and placing the wafer onto the susceptor by the lift pins. Because of these scratches and resulting particles, damage may occur on the device side of the wafer during subsequent thermal processing.

FIG. 1B is an illustration of the process chamber where the lift pins have lowered by the pin lift to place the wafer onto the susceptor. FIG. 1C is an illustration of the susceptor ledge in magnification from View A in FIG. 1B. FIG. 1C illustrates a wafer process position where the susceptor can be raised level with an outer ring. In the process position, the susceptor and outer ring can form a partial seal limiting process gasses from flowing around the susceptor. The ledge may be placed at the outer edge of the susceptor dished-out center area to be slightly raised from the dished-out base surface. The wafer can rest on the ledge to maintain a small gap between the wafer and the susceptor base surface to enable wafer lifting after the deposition process. However, a problem exists during processing in that purge gasses can pass through the holes in the susceptor used by the lift pins and attack the exposed wafer bottom surface (backside).

FIG. 2A is an illustration of a process chamber where susceptor recesses are countersinks and pin ends or heads have conic shaped mating surfaces. The countersink mating with the conic shaped pin head acts to restrict purge gas flow to the wafer bottom surface.

FIG. 2B is an illustration of the countersink feature in magnification from View B in FIG. 2A. Shown in FIG. 2B, the susceptor has a countersunk through hole while the pin end has a mating conic shape to form a seal when the pin is lowered in the process position. The weight of the pin positions the pin end against the countersink of the susceptor with a force of gravity. This contact force can be sufficient to restrict the flow of purge gas from the lower portion of the process chamber to the wafer bottom surface (backside). However, this design still has a problem with pin scratches on the backside of the wafer due to contact by the pin end with the wafer.

FIG. 3 is an illustration of wafer lift fingers made of quartz that pass through holes in the susceptor for wafer lifting. Although wafer scratching is moved to the edge of the wafer, a less critical area, this design has the problem of exposure of the wafer backside surface to purge gases when the pins are lowered and the wafer is placed in the susceptor.

FIG. 4 is an illustration of lift fingers made with quartz and enclosed with a silicon carbide (SiC) sleeve. The SiC sleeve is used to protect the quartz finger from wear and requires the fingers have a locking mechanism to secure the SiC sleeve to the quartz finger. However, this locking mechanism design does not help with problems associated with purge gasses reaching the wafer backside through the holes in the susceptor and the carbide sleeve and locking mechanism adds complexity and cost.

Another technique (not shown) involves the use of an edge ring and pins that are positioned outside the wafer pocket (dished-out center) in the susceptor. This technique is difficult to fabricate, complex and expensive. The edge ring must be open on one side, instead of a full circle, to allow relative motion of the blade that brings in the wafer. Such a shape is more difficult to control flatness. The edge ring also requires removal of enough material from the susceptor to reduce susceptor stiffness yet if material is not removed from the susceptor, the edge ring adds thermal mass to distort the heating and cooling uniformity of the susceptor.

### SUMMARY OF THE INVENTION

An apparatus for translating a wafer with a number of lift pins, each contacting the wafer at an outer diameter edge, is disclosed. The lift pins can be extended and retracted to raise or lower the wafer from a susceptor surface for pickup or release by a robot arm. The lift pins can contact the wafer at the wafer outer diameter edge to place contact at a more benign location on the wafer and to minimize the lift pin contact area overall. When retracted, the lift pins place the wafer onto a susceptor with the lift pins positioned within recesses in the susceptor. The lift pins, retracted within the recesses, may no longer be in contact with the wafer. An end of each lift pin can be shaped to mate with the recess geometry and restrict flow of purge gasses and radiant light from reaching the bottom surface of the wafer.

### BRIEF DESCRIPTION OF THE DRAWINGS

FIG. 1A is an illustration of a process chamber and a wafer raised above a susceptor by lift pins.

FIG. 1B is an illustration of the process chamber and retracted lift pins placing the wafer onto the susceptor.

FIG. 1C is an illustration of an edge of the wafer in contact with the susceptor ledge and the lift pin retracted.

FIG. 2A is an illustration of the process chamber and lift pins forming a seal with susceptor through holes.

FIG. 2B is an illustration of a countersink in the susceptor mating with a conic shaped pin end.

FIG. 3 is an illustration of a process chamber with lift fingers made of quartz to pass through the susceptor for wafer lifting.

FIG. 4 is an illustration of quartz lift fingers coated with silicon carbide and where the fingers have a locking mechanism.

FIG. 5A is a top down view of a wafer positioned in a susceptor to provide a cross-section guide for later FIGS. 5C & 5D and FIG. 7 illustrations.

FIG. 5B shows a 3-dimensional view of one embodiment of the wafer lifting mechanism.

FIG. 5C is a cross-section view of one embodiment of a wafer lifting mechanism illustrating the wafer raised above the susceptor by lift pins.

FIG. 5D is a cross-section view of the embodiment of the wafer lifting mechanism showing retracted lift pins and the wafer positioned on the susceptor in a process position.

FIG. 5E is an illustration of one embodiment of a cross-section of the lift pin head recessed in a counterbore hole having a stepped floor.

FIG. 5F is an illustration of an alternate embodiment of a lift pin head having a stepped feature.

FIG. 5G is an illustration of an alternate embodiment of a lift pin head having a conic surface.

FIG. 5H is an illustration of one embodiment of a top view of a wafer resting on a continuous susceptor ledge.

FIG. 5I is an illustration of an alternate embodiment of a top view of a wafer resting on a discontinuous susceptor ledge.

FIG. 5J is an illustration of an alternate embodiment of an susceptor ledge that is angled.

FIG. 6 is an illustration of one embodiment of the lift pin during fabrication on a process mandrel.

FIG. 7 is an illustration of an alternate embodiment of a lift pin where the lift pin is angled relative to travel by the susceptor.

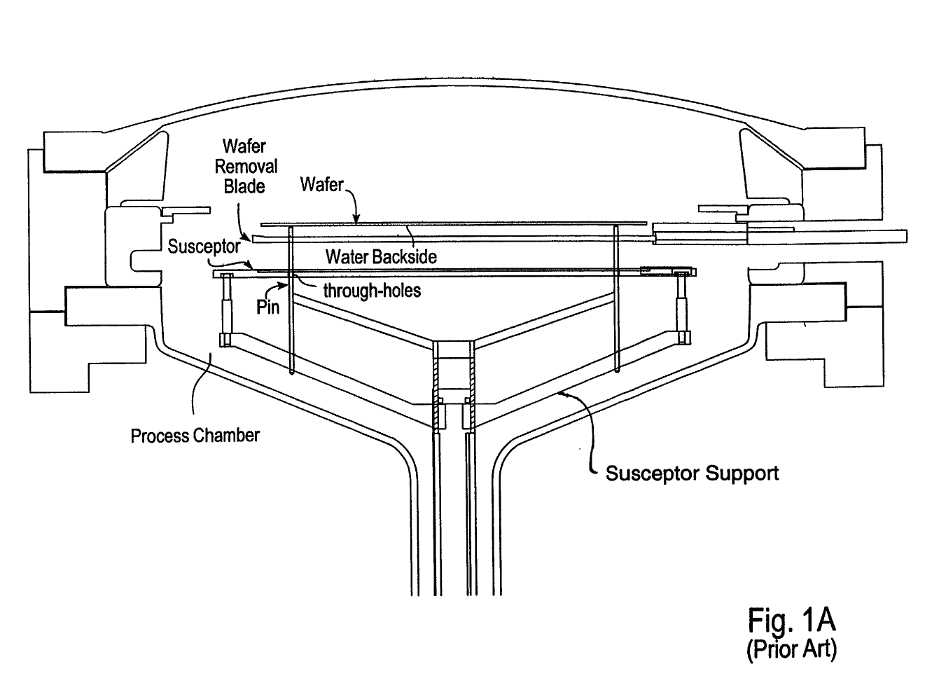

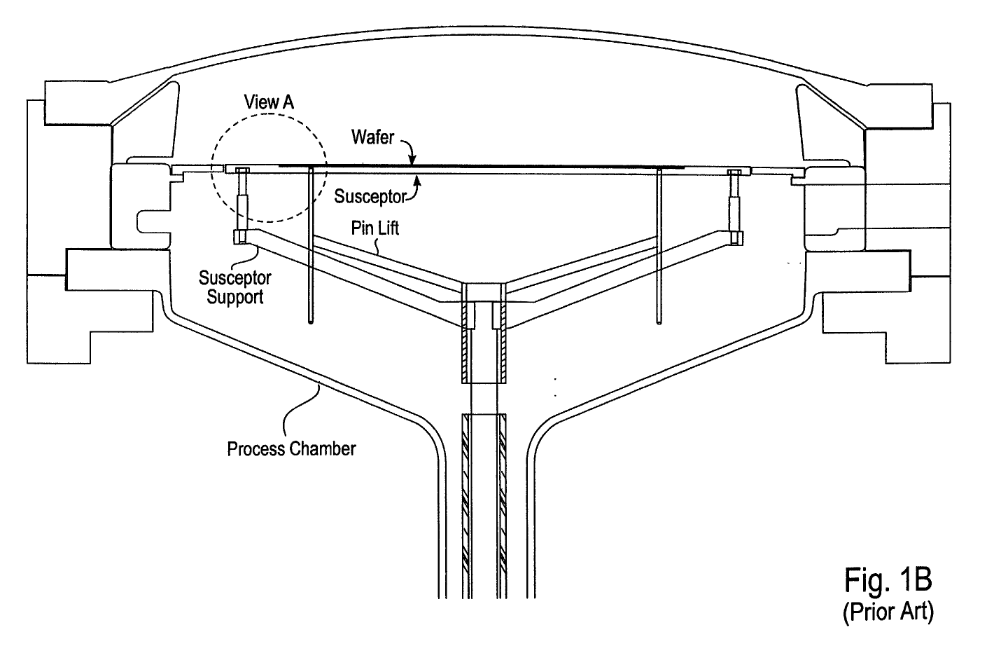

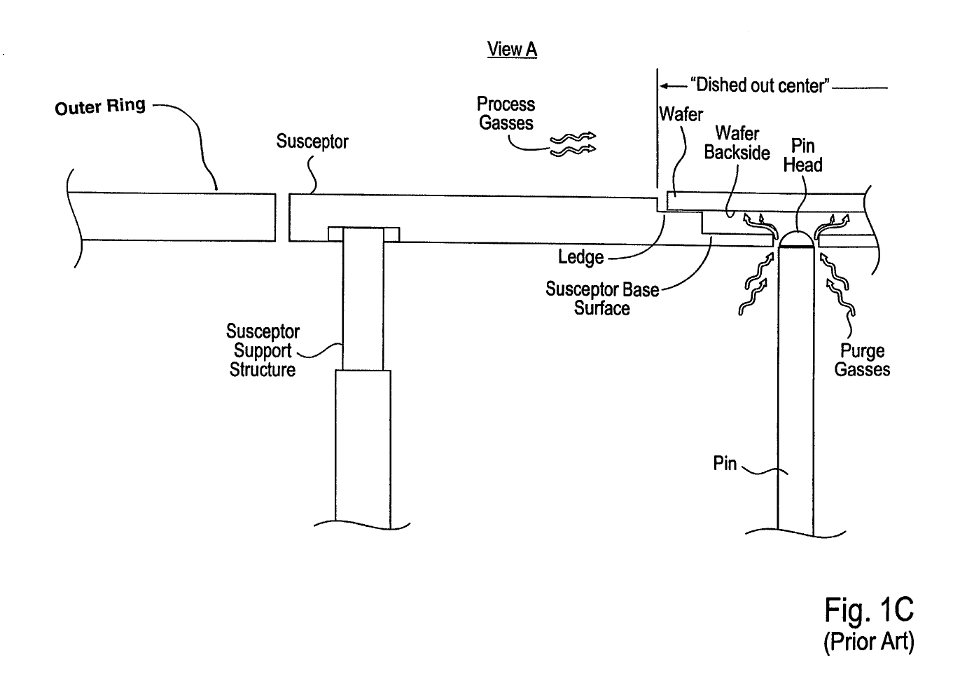

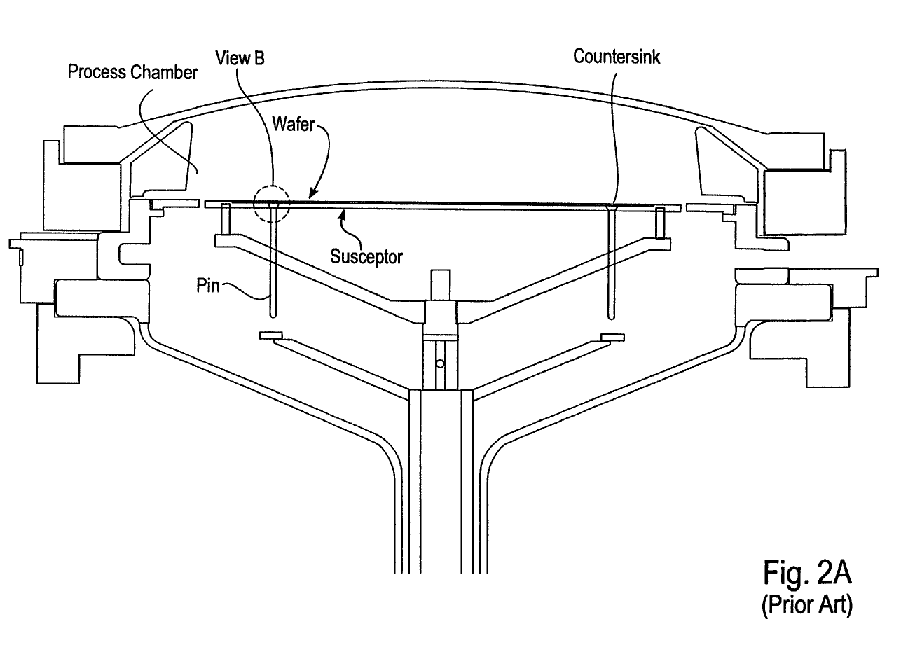

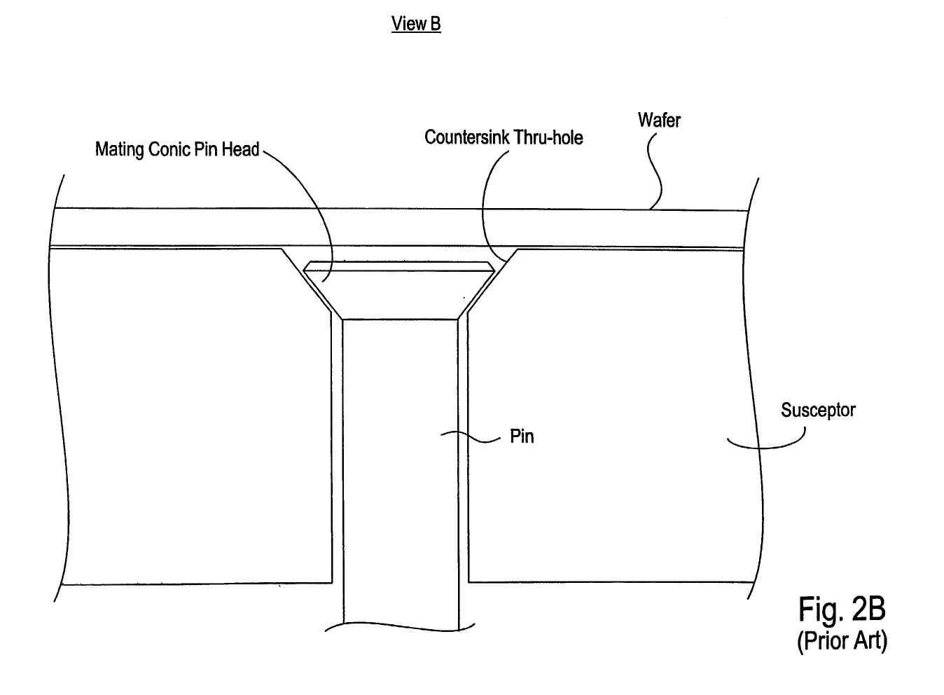

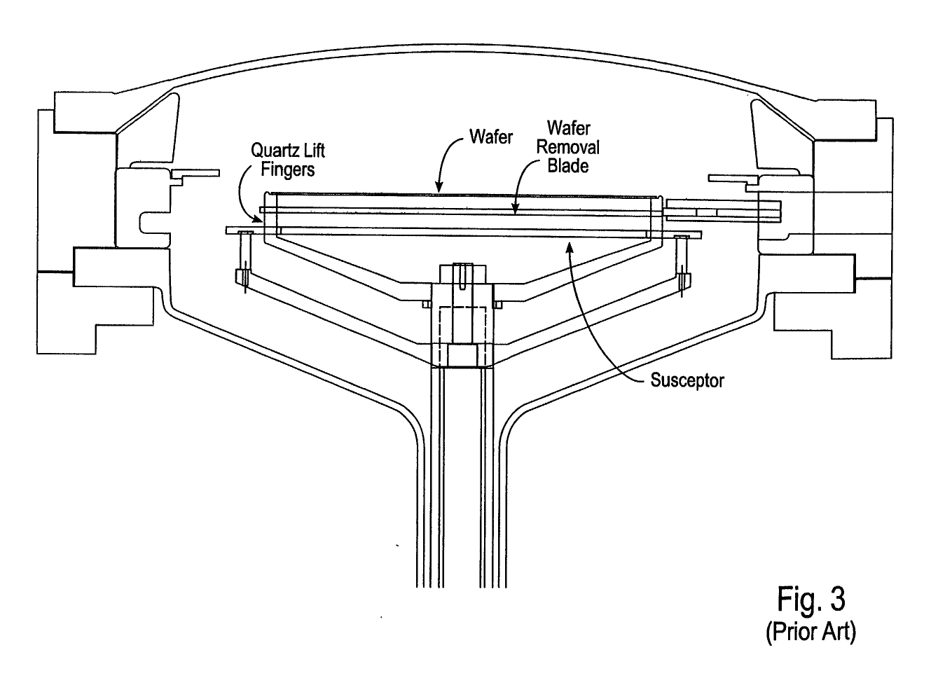

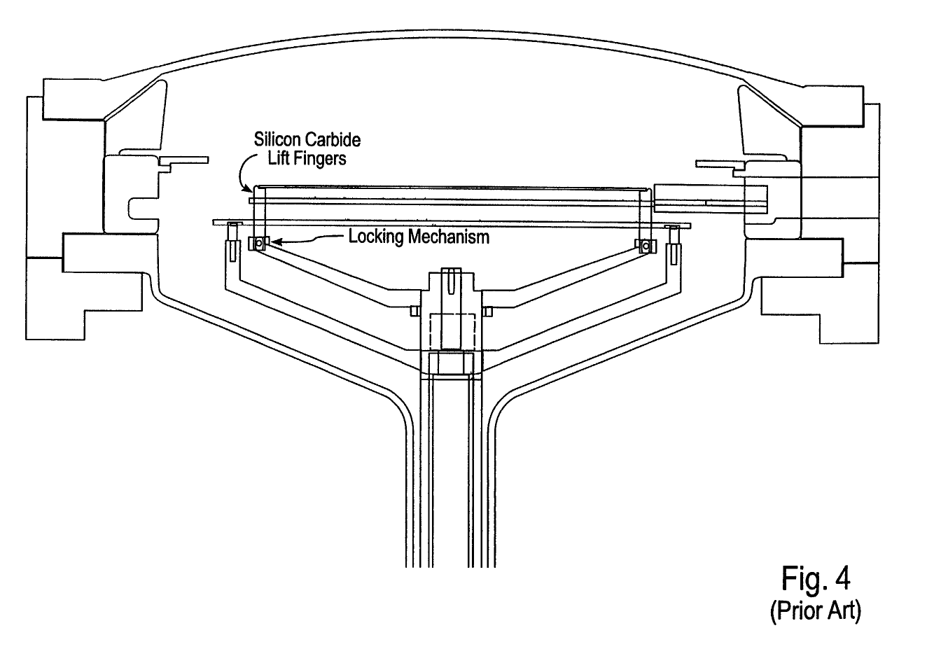

### DETAILED DESCRIPTION OF THE PRESENT INVENTION

Within a wafer process chamber such as, for example, used for chemical vapor deposition (CVD) of polysilicon or epitaxial films, a method and apparatus for raising and lowering a wafer onto a susceptor that reduces wafer damage, is described. Embodiments of the present invention can translate a number of wafer lift pins through holes in the susceptor to contact the wafer near or at the wafer outer diameter edge. Such contact occurring at the more benign outer edge of the wafer can result in less damage to the wafer due to translating the wafer by the lift pins. In addition, a closed-hole feature that results from mating the susceptor through hole areas with the lift pin heads when the lift pin heads are lowered for processing, can reduce wafer backside exposure to purge gasses and radiant light.

The wafer lift apparatus can place and remove a wafer from a top surface of a circular dish-shaped plate, i.e. a susceptor. While the wafer is positioned on the susceptor, process gasses can be introduced into the wafer process chamber to deposit a film onto a top surface of the wafer. A purge gas such as hydrogen can be introduced into the bottom area of the process chamber to prevent process gas flow to the bottom of the chamber.

The invention can restrict purge gas flow to the wafer bottom side through the use of a closed-hole shape provided in both the lift pin heads and mating susceptor surfaces. When the lift pins are retracted (i.e. lowered), each lift pin head can contact the mating susceptor surface to close off any purge gas path through the holes in the susceptor that are used by the lift pins, i.e. the closed hole feature. If not blocked, purge gasses entering the bottom portion of the process chamber can pass through the susceptor through holes and around each lift pin to reach the bottom side of the wafer. Exposing the bottom side of the wafer to purge gas should be avoided or minimized since the purge gas can cause a change in the surface finish of the wafer.

The lift pin heads can each have a raised feature to restrain the wafer from shifting radially while the wafer is raised above the susceptor. When the wafer is resting on the susceptor and each lift pin head is no longer maintaining the wafer in a raised position, the raised features of the lift pin heads can be high enough to still restrain the wafer from radial movement.

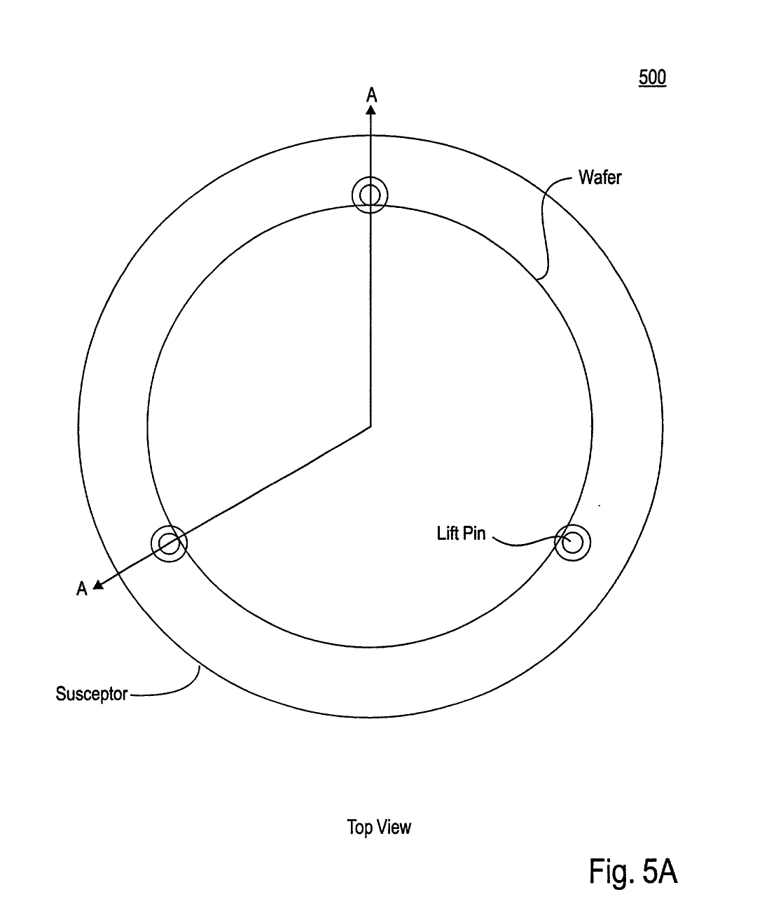

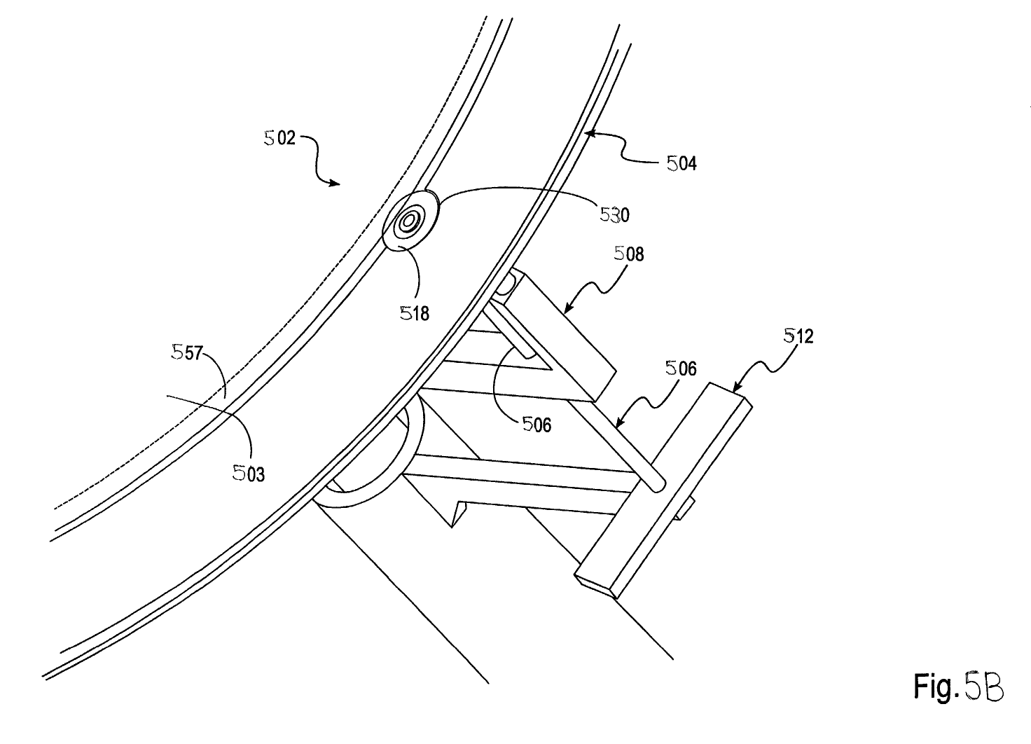

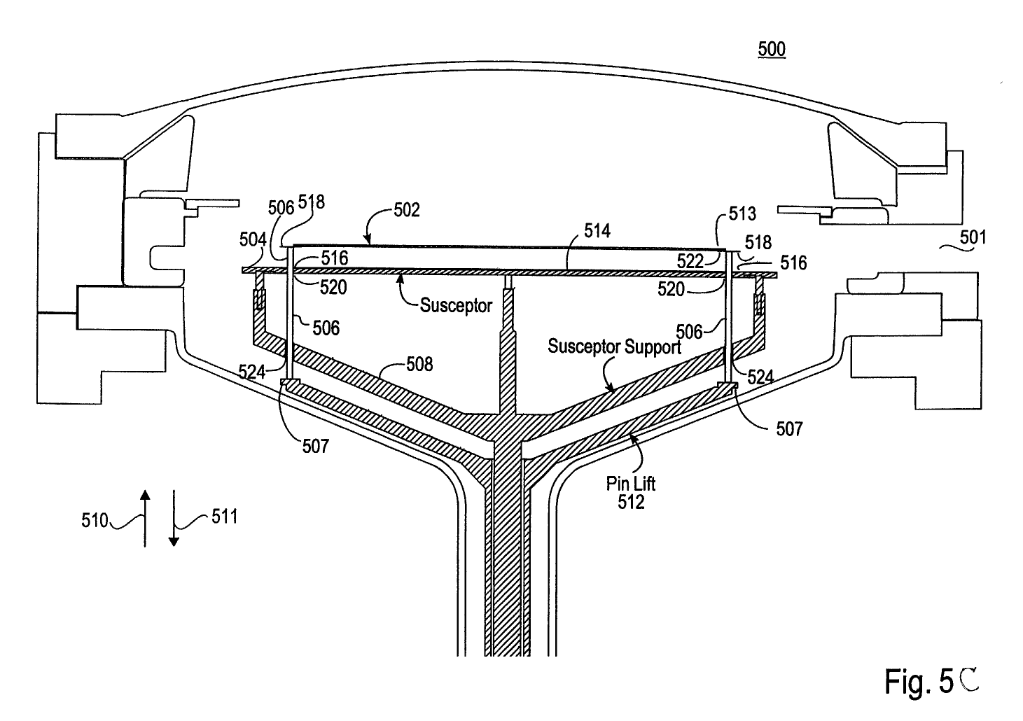

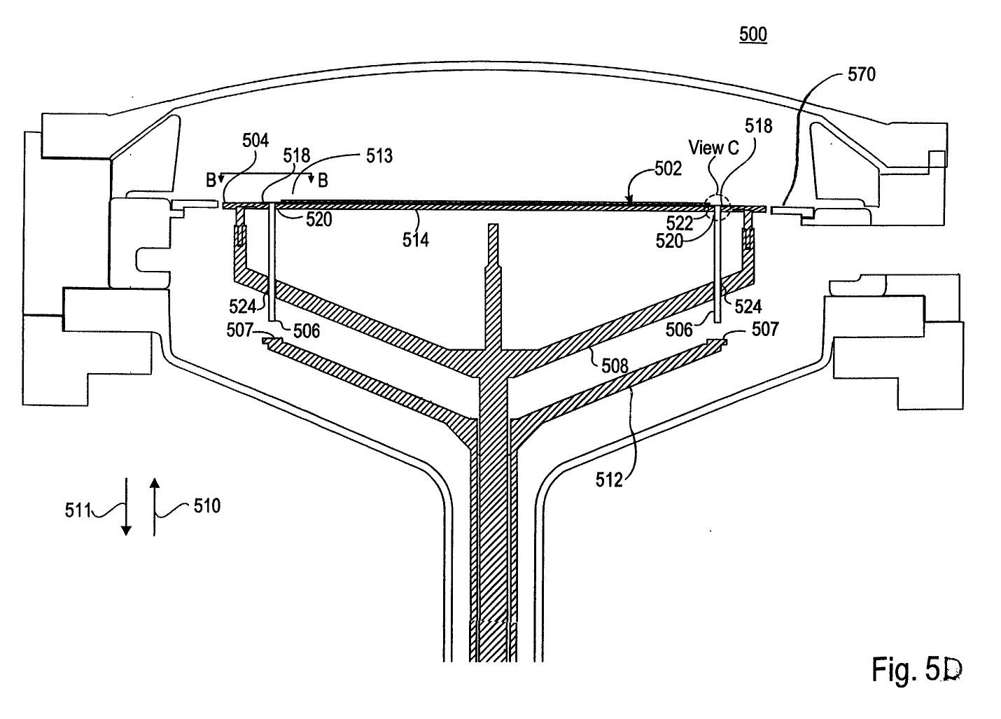

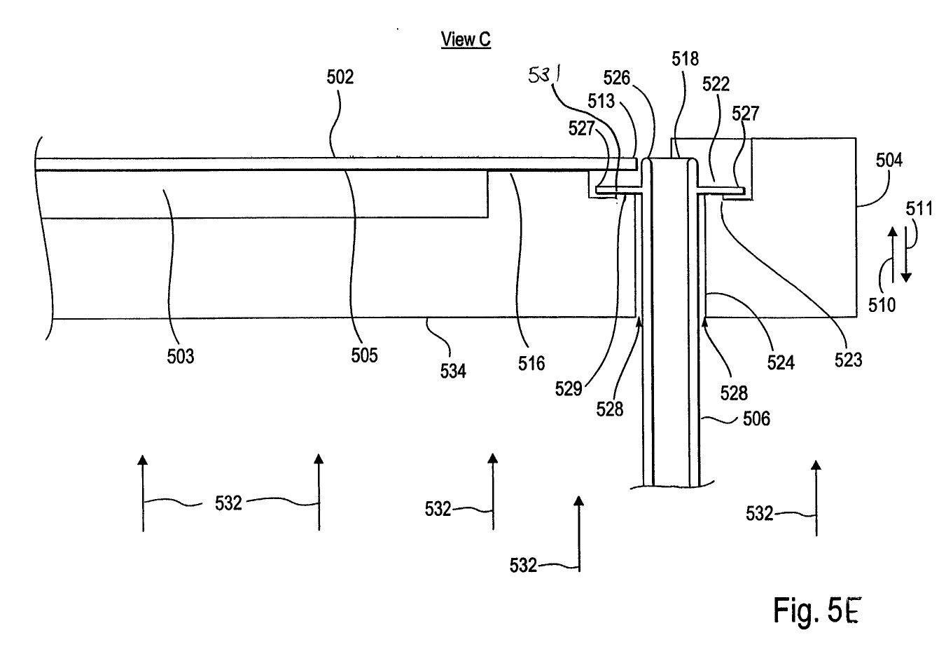

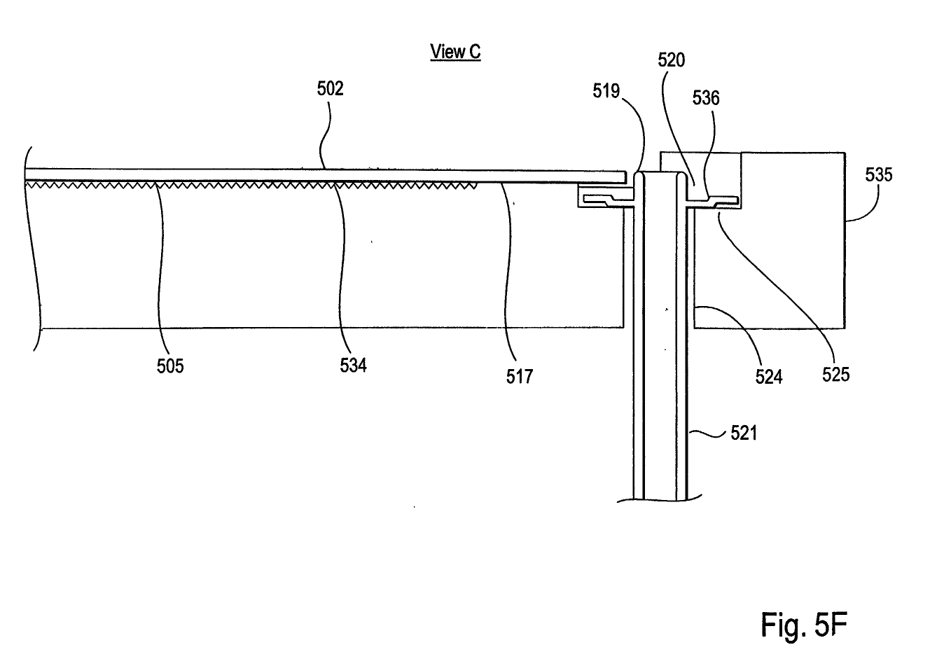

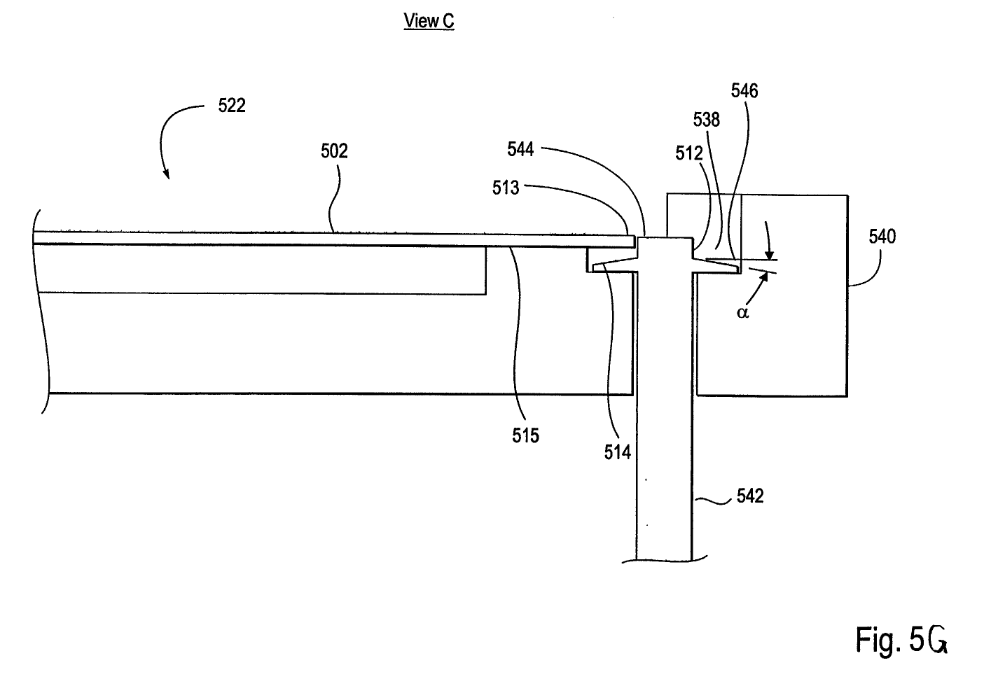

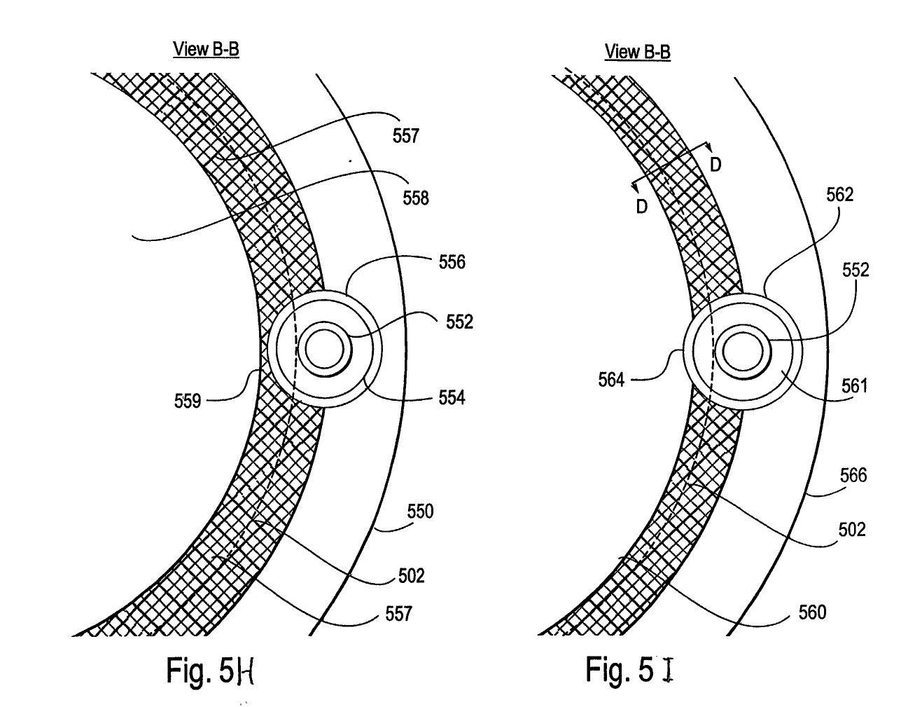

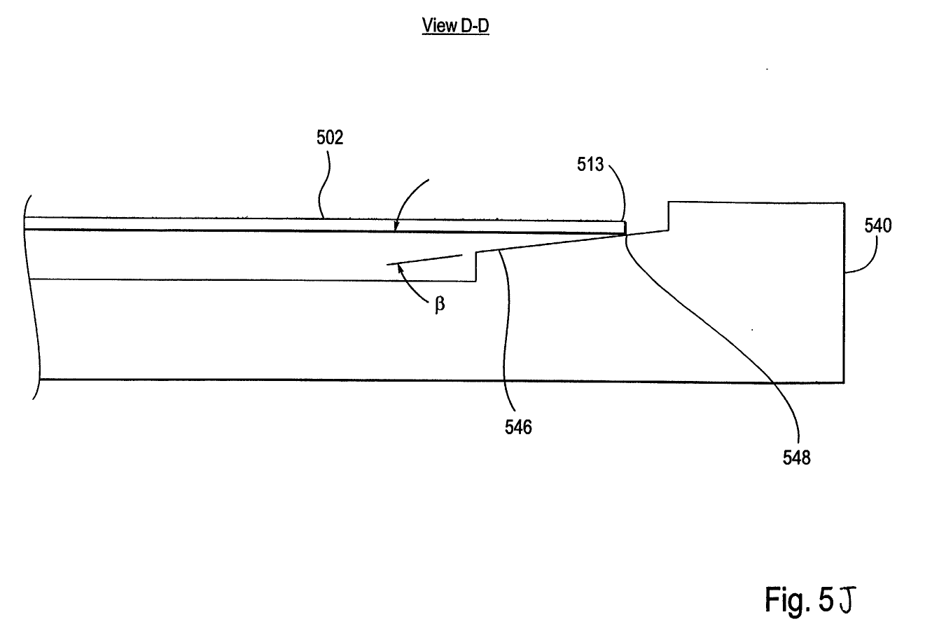

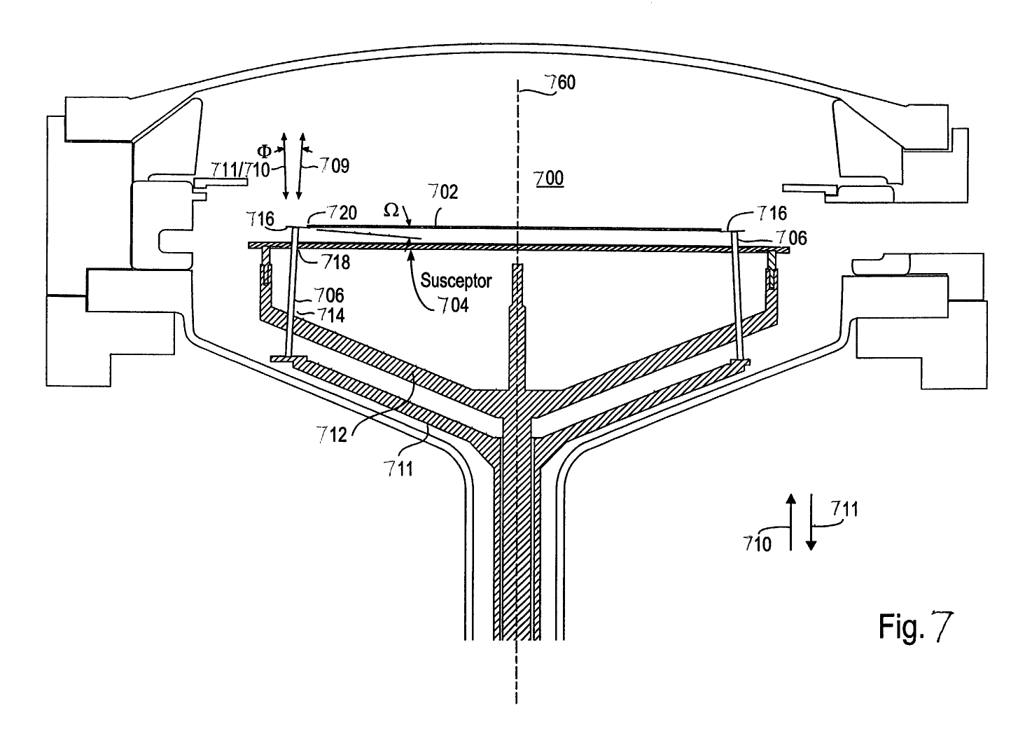

FIG. 5A is an illustration of a top view of an embodiment of a wafer (in phantom) resting on a susceptor with lift pins retracted. This top view is used to define Section A-A used in the FIGS. 5C & 5D and FIG. 7 illustrations.

FIG. 5B is an illustration of one embodiment of a closed-edge lift pin and a wafer in a susceptor. FIG. 5B shows a 3D view of the wafer 502 resting on a continuous ledge 557 that is positioned in the dished out center 503 area of a susceptor 504. The susceptor 504 is shown attached to a susceptor support structure 508. With the pin lift 512 and lift pin(s) 506 retracted, the wafer 502 can rest on the susceptor ledge 557 with each lift pin head 518 recessed into a hole that is a counterbore 530.

FIG. 5C is a cross-section view of one embodiment showing a process chamber with a wafer in the transfer position. FIG. 5C illustrates a condition where the pin lift 512, the susceptor support 508, the susceptor 504 and the wafer 502 have translated down 511 from a process position to place a wafer 502 level with a transfer slit 501 (slit) for wafer 502 transfer. The wafer process chamber 500 can contain lift pins 506 that pass through holes 520 in the susceptor and through holes 524 in a susceptor support structure 508 to contact a moveable pin lift 512 for translating the wafer 502 off and onto the susceptor 504. The diameters of the lift pins 506 are smaller than the through hole 524 diameters in the susceptor support structure 508 and the susceptor through holes 520 such that the lift pins 506 are free to translate 510 and 511. The susceptor 504, attached to the susceptor support 508, can provide a fixed platform for holding the wafer 502 during processing.

The pin lift 512 and the susceptor 504/susceptor support 508 can both translate in both an up 510 and a down 511 direction. To add and/or remove a wafer 502 from the process chamber 500; the wafer 502, the lift pins 506, the pin lift 512, the susceptor 504, and the susceptor support 508 structures can be lowered to a point where the pin lift 512 stops and the susceptor 504/susceptor support 508 continues to translate down 511. This method of translation 510 and 511 can both drop the wafer 502 to be level with the slit 501 and lift the wafer 502 off the susceptor 504.

A direct link now exists between the pin lift 512 and the wafer 502 and any further upward 510 movement by the pin lift 512 will translate the wafer 502 upward 510. For this embodiment, once the direct link is made, a distance translated by the pin lift 512 is equal to the distance translated by the wafer 502, however, this may not be true for other embodiments such as described in FIG. 7 below. The lift pins 506 can be raised 510 until the wafer 502 is approximately level with a slit 501 that is mid-level in the process chamber 500. From this raised wafer position, the wafer 502 can be transferred to and from the process chamber 500 by a robot (not shown). The contact points 507 on the pin lift 512 can be local flat areas as shown or can be a continuous feature such as, for example, a ring (not shown).

FIG. 5D is an illustration of an embodiment where the lift pins are retracted and the wafer positioned on the susceptor in a process position. FIG. 5D illustrates the wafer process position, i.e. the susceptor 504 raised to a level with a ring 570. The pin lift 512 and the lift pins 506 in contact with the wafer edge 513, i.e. the outer diameter of the wafer 502, have translated the wafer 502 downward 511 onto the susceptor 504. The lift pin heads 518 can each contact a floor 529 of one of the recesses 522 (such as, for example, shown in FIG. 5E below) in the susceptor 504 and may no longer be in contact with the wafer 502. The lift pins 506 are essentially free floating within holes 520 in the susceptor 504 and holes 524 in the susceptor support 508 to be limited in “up travel” 510 by movement of the pin lift 512 and limited in “down travel” 511 by the susceptor 504 surfaces when contacting the pin lift heads 518 or by pin lift 512 travel.

Alternatively, in another embodiment for a process chamber (not shown), the wafer process position and the slit position can be reversed where the slit is above the wafer process position.

FIG. 5E and 5F are illustrations of a lift pin recessed within a susceptor at the process position. FIG. 5E is one embodiment of a magnification of View C in FIG. 5D and shows the lift pin head 518 recessed in a counterbore hole (counterbore) 522 such that the retracted pin head 518, now contacting a portion 529 of stepped floor 523 of each recess 522, is not in contact with the wafer 502. With the pin lift 512 (FIG. 5D above) lowered 511, gravity acting on the lift pin 506 can maintain the lift pin head 518 in contact with floor, i.e. the counterbore bottom contact surface 529. The stepped feature 523 can reduce the contact surface area between the counterbore 522 floor and the mating lift pin head 518 and can also create a longer path for the diffusion of reactive gasses to reach the first point of contact 531 between the contact surface of the floor 529 and the disk 527 portion of the pin head 518. The lift pin head 518 may still stick to contact areas 529 of the susceptor 504 as a result of such reactive gasses, and the reduced contact area 529 can reduce the force necessary to raise each lift pin head 518 off the susceptor 504 after a processing cycle.

In this retracted lift pin 506 position, the wafer 502 can rest on a ledge 516 in the susceptor 504 located at the edge of a dished out center 503 of the susceptor 504. The ledge 516 can be located close to or at the wafer outer diameter edge 513. The wafer 502 can rest on the ledge 516 during processing to provide support to the wafer 502. Support by the ledge 516 can limit wafer 502 distortion such as bowing that could result from gravity and process heat if the wafer 502 were only supported by the small local surface areas of the lift pin heads 527.

Still referring to FIG. 5E, the wafer 502 can be maintained in radial position by a raised circular lip 526 located on the lift pin head 518. Dimensional tolerancing (i.e. the dimension and dimension ranges of the individual parts as well as their inter-related dimensions) of the various components (i.e. the pin lift through holes and their true position, the susceptor through holes and their true position, the lift pin diameters, the lift pin head dimensions, the wafer diameter, etc.) can maintain the circular lip 526 in a position to limit radial movement of the wafer positioned within the lift pin heads when the lift pin heads 518 are retracted or extended (not shown).

The lift pin head 518 can have a circular flange 527, shaped like a disk that can mate with a contact surface 529 portion of the stepped bottom 523 of a counterbore 522 and with the wafer 502. When the lift pin 506 is fully retracted and the disk 527 is resting on the bottom of the counterbore 522, the disk 527-contact surface 529 can provide a restriction to purge gas flow 528 coming up from below and thus limit the purge gas 528 from passing around the lift pins 506 and through each through hole 520 in the susceptor 504. As a result, closed-hole restriction of purge gas flow 528 can limit purge gasses from reaching the wafer bottom surface 505 during wafer 502 processing. The use of the closed-hole feature can restrict purge gasses 528 from reaching the wafer bottom surface 505.

The closed-hole feature on the lift pin 506 can block radiant heat 532, from heaters below (not shown) that heat the susceptor bottom surface 534. Without the closed-hole feature, the radiant heat 532 might pass through the susceptor through holes 528 to reach the wafer 502 causing non-uniform heating of the wafer 502 at local spots near the outer edge 513.

FIG. 5F is an illustration of an alternate embodiment shown in the magnification of View C for the closed-hole edge lift pin apparatus. FIG. 5F illustrates a lift pin 521 having a lift pin head 519 recessed within a counterbore 520 and a wafer 502 resting on a ledge 517. The lift pin head 519 has a staggered feature 536 that can reduce surface area contact between the lift pin head 519 and the counterbore floor 525. As stated above, reduced contact area can reduce the amount of sticking between the lift pin head 519 and the floor 525 after a process cycle. In addition, the FIG. 5F illustration shows a susceptor 535 without a dished-out center where, instead, the center surface area is roughened 534 such as, for example, with knurling or by machining concentric grooves or with a spiral ridge. Such a roughened surface 534 can create high and low points on the susceptor surface to make it easier to lift the wafer 502 off the susceptor 535 while supporting the wafer 502 across the entire wafer surface 505.

FIG. 5G is an illustration of an alternate embodiment of a magnification of View C for the closed-hole edge lift pin. The FIG. 5G illustration shows the lift pin 542 within a recess that is a counterbore 538 in the susceptor 540 and a wafer 502 positioned on a susceptor ledge 515. The lift pin 542 can have a portion of the lift pin head 544 in the shape of a shallow cone 514, where in one embodiment, the cone 514 can include an angled surface, alpha (α), in the range of approximately 0.1-7.0 degrees, and in an alternate embodiment, an approximate 2.5 degree angle can be used (the angle measured from the horizontal such as the hypothetical surface 546). As a result, when the pins 542 contact the wafer 502 (not shown), the wafer outer diameter edge 513 can contact the cone surface 514 of the lift pin head 544. A benefit of this contact between the wafer edge 513 and the cone surface 514 is that the contact area with the wafer 502 will be small, approaching a point contact. At the same time, the wafer outer diameter 513 may also contact the cylindrical portion 512 of the lift pin head 544, which can aid in positioning the wafer 502 with the susceptor 540 by limiting radial travel by the wafer 502. In this embodiment, the lift pin 542 is a solid pin, i.e. not a hollow tube as shown in previous embodiments.

FIGS. 5H and 5I represent illustrations of View B-B from FIG. 5D. FIG. 5H is an illustration of one embodiment of the wafer resting on a continuous ledge. As shown in FIG. 5H, the ledge 557, on which the wafer 502 rests, is cross-hatched and the edge of the wafer 502 is shown as a dotted line, with the wafer 502 transparent. Raised portions 552 on the lift pin head 554 can aid in wafer 502 positioning by contacting the wafer 502 to block radial travel by the wafer 502. The lift pin head 554 can be recessed within the counterbore 556 when the wafer 502 is positioned on the susceptor 550 for processing. The ledge 557, located within a susceptor dished-out center 558, can provide support for the wafer 502 during processing. In this embodiment, the ledge 557 is continuous to run 360 degrees around. That is, the ledge 557 is not broken completely through such as at locations where each counterbore 556 is placed.

FIG. 5I is an illustration of another embodiment of a ledge supporting the wafer 502. The wafer 502 (edge shown in phantom for clarity) is illustrated resting on the susceptor ledge 560 with the lift pin head 561 recessed. The ledge 560 may not be continuous (i.e. discontinuous) around the wafer 502 resulting from the position of the counterbore holes 562 in the susceptor 566, each of which can intersect the ledge 560 providing a break 564 in the ledge 560. The break(s) 564 in the ledge 560 can be small enough to not detract from the overall support provided the wafer 502 by the ledge 560 during processing.

FIG. 5J is an illustration of another embodiment of a susceptor ledge where the ledge is angled. FIG. 5J is a cross-section of the susceptor 540 at view D-D from FIG. 51. The susceptor ledge 546 can be at an angle β, where β can be in approximately 1.5 degrees from horizontal however, in alternate embodiments, a range of approximately 0.1-7.0 degrees from horizontal may be used. The angled ledge 546 can slope down toward the center of the susceptor 540 to allow the wafer 502 outer diameter edge 513 to rest on the angled ledge surface 546. As a result, contact 548 between the wafer 502 and the susceptor 540 is reduced to a small area.

It is to be understood that the floor of the susceptor that is capable of contacting the lift pin heads, when the lift pins are retracted onto the susceptor, can be floors existing in a variety of shapes. These shapes can be other than the local circular features, i.e. the counterbores, which have been described above. The floor can be shapes, such as, for example, a series of partial rings, a continuous ring a series of partial grooves or a continuous groove that runs around the susceptor.

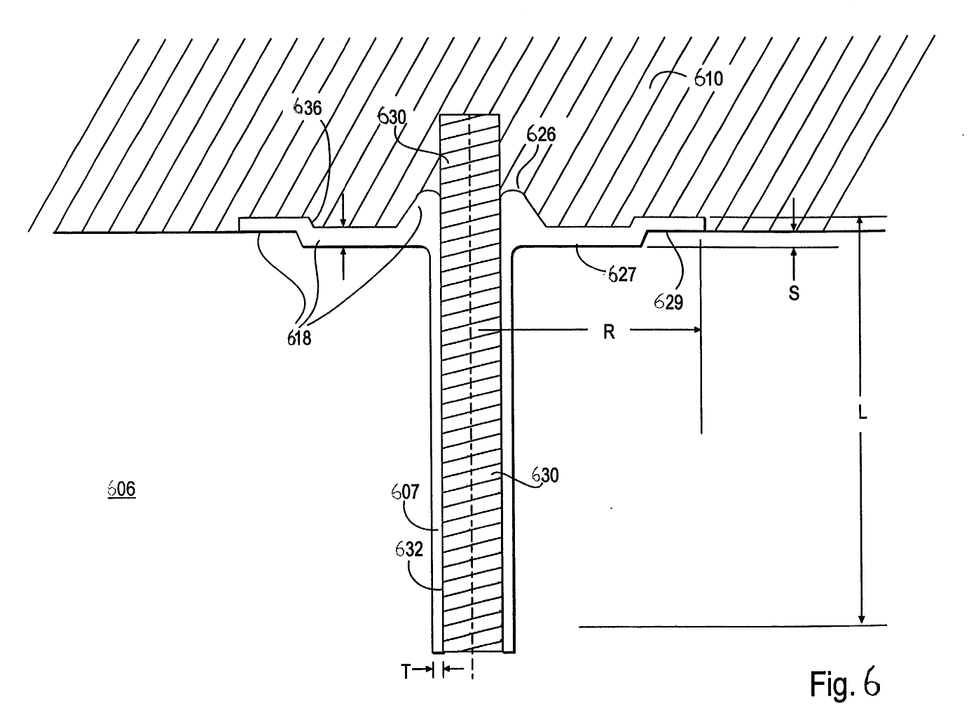

FIG. 6 is an illustration of one embodiment of a lift pin during processing where the lift pin is positioned in a mandrel used during lift pin fabrication. To avoid metal contamination of a wafer (not shown) and yet survive the process environment, each lift pin 606 can be constructed of a non-metal such as silicon carbide, which can survive continuous temperatures up to approximately 4800 degrees F. In this embodiment, the lift pin 606 can be fabricated as a shell or hollow tube. The lift pin 606 can be produced on a graphite mandrel 610 and 630 where the silicon carbide pin material is deposited directly. The mandrels 610 and 630 are in the shape of the surfaces of the lift pin 606 to be manufactured and where silicon carbide can deposited by a process such as, for example, CVD that can provide the buildup against the mandrel surfaces as net (final shape). Additionally, one or more of the lift pin dimensions, such as, for example, the length L, can be overstock (i.e. larger than net) to be later machined to a net value.

As a result, a lift pin can be produced by depositing silicon carbide onto the graphite mandrel 610 and 630. The female mandrel 610 can be formed in the shape required to meet some of the lift pin head 606 inner and outer surface dimensions. For this embodiment, the female mandrel 610 can form the shape for the stepped disk area 626 and 627 of FIG. 5F (i.e. the closed-hole feature) and the raised area 626 used for radially positioning the wafer during processing. A male mandrel 630 can be placed into the female mandrel 610 to form the lift pin I.D. surface 632 and create the tubular portion (pin body) 607 of the lift pin 606.

After deposition of the SiC, the exposed SiC surfaces can be machined to provide the net lift pin 606. The machining can including cutting the lift pin 606 to a net length L, the step height S in the disk areas 627 and 629 as well as the radius R of the lift pin head 618. In one embodiment, the net thickness T of the pin tube 607 can be machined to a range of approximately between 0.010-0.040″. However, in an alternate embodiment, a range of approximately between 0.018-0.028″ may be used. The length L of the tube section 607 can be approximately 4.0″. A net radius R for the lift pin head 618 can be approximately in the range of between 0.2-0.4″. The step height S can be approximately 0.003″. A thickness for the flange (disk) area 627 and 629 can be in the range of approximately 0.020-0.040″. The graphite mandrels 610 and 630 can be separated from the lift pin 606 by a burn off process and where the excess dimensions of the pin 606 can be machined as described above to net either before or after mandrel 610 and 630 separation.

In an alternate embodiment (not shown), a solid SiC pin can be placed into the mandrel and a deposition of SiC can form the pin head and at the same time attach the pin head to the pin. This deposition of SiC can provide an overstock condition to the pin head so that surfaces of the pin head not contacting the mandrel may have to be machined to a net dimension. In addition, the deposition of SiC onto the pin may create an overstock condition on the pin and the pin may also have to be machined.

In yet another alternate embodiment (not shown), the pin head and a tubular pin body may each be made separately and then an end of the tubular pin body can be placed in contact with the pin head. A later deposition of SiC can fused or grow together the pin head with the pin body. Finally, surfaces accessible to machining may then be machined to provide the net dimensions for the lift pin.

FIG. 7 illustrates a wafer lifting mechanism 700 where the direction of travel 709 for the lift pins 706 is at an angle φ to the up 710 and down 711 movement of the wafer 702 and the pin lift structure 712. The lift pins 706 are each “cocked” inward the angle φ toward the wafer circular center 760, which can be approximately in the range of between 0.2-3.0 degrees with a preferred angle φ of 0.7 degrees (relative to vertical 709). In this embodiment, the lift pin heads 716 are shaped like a disk (as shown in FIG. 5E above) and angle φ will result in a lift pin disk surface 716 angle Ω, relative to the wafer 702 (which is horizontal) that is equivalent to φ. This angle Ω, can place the wafer 702 in contact with each lift pin 706 at a single wafer edge point 720 (until contact is broken and the lift pin heads 716 are fully recessed) which can reduce or eliminate damage to the wafer 702 during the raising and lowing process.

Alternatively, the lift pins 706 can be angled at ambient temperature so that the lift pins 706 become normal to the wafer 702 at processing conditions, i.e. after thermal expansion. In either case, the angle φ for the lift pins 706 can be set by dimensional tolerancing such as by adjusting the true position on the susceptor 704 hole 718 pattern relative to the true position of the susceptor support 708 hole 714 pattern.

We claim:

1. An apparatus, comprising:
a susceptor having a plurality of through holes;
a plurality of lift pins each positioned within one of the plurality of through holes, each lift pin having a lift pin head capable of translating a wafer by contacting the wafer at the wafer outer diameter edge,
the plurality of lift pins capable of extending to lift the wafer off the susceptor; and
the plurality of lift pins capable of lowering to place the wafer onto the susceptor, wherein upon placing the wafer onto the susceptor, each of the plurality of lift pin heads are capable of contacting a floor of the susceptor for restricting flow of a gas through the plurality of through holes.

2. The apparatus of claim 1, wherein the susceptor has a dished out center and a ledge is positioned within the dished out center for supporting the wafer.

3. The apparatus of claim 2, wherein the ledge is a continuous circular surface.

4. The apparatus of claim 2, wherein the ledge is discontinuous.

5. The apparatus of claim 1, wherein the susceptor has a roughened center surface area.

6. The apparatus of claim 2, further comprising a plurality of recesses within the susceptor each containing one of the plurality of through holes, wherein when retracted, each of the plurality of lift pin heads are not capable of contacting the wafer when contacting the floor.

7. The apparatus of claim 6, wherein the plurality of recesses are positioned such that a portion of each recess opens into the dished out center area.

8. The apparatus of claim 1, wherein the plurality of lift pins each has a surface that contacts the wafer outer diameter edge at an angle greater than zero from horizontal.

9. The apparatus of claim 8, wherein the angle is in the range of approximately between 0.1-7.0 degrees relative to horizontal.

10. The apparatus of claim 8, wherein the angle is approximately 2.5 degrees relative to horizontal.

11. The apparatus of claim 1, wherein the plurality of lift pins each has a stepped surface.

12. The apparatus of claim 1, wherein the plurality of lift pins are made of silicon carbide.

13. The apparatus of claim 8, wherein the plurality of lift pins each has a cone shaped surface to contact the wafer outer diameter edge.

14. The apparatus of claim 1, wherein a direction of travel for the plurality of lift pins is not parallel to a direction of travel for the susceptor.

15. The apparatus of claim 14, wherein the direction of travel for the plurality of lift pins is approximately between 0.1-7.0 degrees from the direction of travel for the susceptor.

16. The apparatus of claim 1, wherein the plurality of lift pins each are a hollow tube.

17. The apparatus of claim 1, wherein at least three of the lift pin heads can have a raised feature to restrain the wafer from shifting radially.

18. The apparatus of claim 1, wherein the plurality of lift pins are a solid tube.

19. The apparatus of claim 1 capable of positioning the wafer on the susceptor, and where the plurality of lift pin heads are not in contact with the wafer.

20. The apparatus of claim 1, wherein upon placing the wafer onto the susceptor, each of the plurality of lift pin heads are capable of contacting a floor for restricting radiant heat from reaching the wafer.

21. The apparatus of claim 2, wherein the ledge is angled.

22. The apparatus of claim 21, wherein the ledge angle is approximately between 0.1-7.0 degrees sloped down toward the susceptor center to place the wafer outer diameter edge in contact with the ledge surface.

23. The apparatus of claim 1, wherein the floor of the susceptor, capable of contact by the plurality of lift pins, is stepped.

24. An apparatus, comprising:
a susceptor having a plurality counterbore holes having a plurality of through holes positioned within;
the susceptor having a ledge positioned within a dished out center capable of supporting a wafer
a plurality of lift pins positioned within the through holes, each lift pin having a lift pin head capable of translating the wafer by contacting the wafer at an outer diameter edge,
the plurality of lift pins capable of extending to lift the wafer off the susceptor; and
the plurality of lift pins capable of retracting to place the wafer onto the susceptor, wherein upon placing the wafer onto the ledge, each of the plurality of lift pin heads are capable of contacting a floor of each of the plurality of couterbore holes for restricting flow of a gas through the plurality of counterbore holes.

25. The apparatus of claim 24, wherein the plurality of lift pins each has a surface that contacts the wafer outer diameter edge at an angle greater than zero from horizontal.

26. The apparatus of claim 25, wherein the plurality of lift pins each has a stepped surface.

27. An apparatus, comprising:
a plurality of lift pins capable of translating a wafer by contacting the wafer near the wafer outer diameter edge;
a pin lift capable of moving the plurality of lift pins; and
means for reducing the contact area between the wafer and each of the plurality of lift pins during wafer translation.

28. The apparatus of claim 27, further comprising:
means for contacting the wafer edge at an angle greater than zero with the horizontal.

29. The apparatus of claim 27, further comprising:
means for reducing exposure of a bottom side of the wafer to a purge gas.

30. The apparatus of claim 27, further comprising:
means for reducing the contact area between the wafer and the susceptor.

31. The apparatus of claim 27, further comprising:
means for restricting process gas from reaching a contact point between the lift pin head and a floor of a susceptor.

32. A method, comprising:
positioning the wafer on a plurality of pins extended in a direction, where the plurality of pins contact the wafer at the wafer outer diameter edge; and
translating the plurality of pins in an opposite direction until, each of the plurality of pins is positioned in a recess in a susceptor, and the plurality of pins are not in contact with the wafer.

33. The method of claim 32, further comprising:
contacting the wafer with lift pins having lift pin heads that are angled relative to horizontal; and
translating the wafer by the plurality of pins in a pin direction that is at an angle in the range of approximately 0.1-7.0 degrees from the direction of wafer travel.
